(19) United States
(12) Patent Application Publication
(10) Pub. No.: US 2021/0210656 A1
(43) Pub. Date: Jul. 8, 2021

(54) METHOD FOR MICRO-LED EPITAXIAL WAFER MANUFACTURING AND MICRO-LED EPITAXIAL WAFER

(71) Applicant: CHONGQING KONKA PHOTOELECTRIC TECHNOLOGY RESEARCH INSTITUTE CO., LTD., Chongqing (CN)

(72) Inventors: Shun-kuei YANG, Chongqing (CN); Chia-hung HUANG, Chongqing (CN); Ya-wen LIN, Chongqing (CN); Kuo-tung HUANG, Chongqing (CN)

(21) Appl. No.: 17/209,708

(22) Filed: Mar. 23, 2021

Related U.S. Application Data
(63) Continuation of application No. PCT/CN2019/125477, filed on Dec. 16, 2019.

(51) Int. Cl. H01L 33/20; H01L 33/00

(52) U.S. Cl. CPC H01L 33/20; H01L 33/0093

(57) ABSTRACT

A method for micro-LED epitaxial wafer manufacturing and a micro-LED epitaxial wafer are provided. The method includes the following. For each growth region of a micro-LED chip on a growth substrate, photoresist is applied to the growth region. For each growth region, an epitaxial isolation wall is grown at a boundary of the growth region. For each growth region, the photoresist on the growth substrate is removed with the epitaxial isolation wall remained. For each growth region, a first semiconductor layer, a light-emitting layer, and a second semiconductor layer are grown in the growth region to obtain a micro-LED epitaxial structure. The growth substrate is cut along the epitaxial isolation wall, to obtain at least two micro-LED epitaxial structures.

### CROSS-REFERENCE TO RELATED APPLICATION(S)

This application is a continuation of International Application No. PCT/CN2019/125477, filed on Dec. 16, 2019, the disclosure of which is hereby incorporated by reference in its entirety.

### TECHNICAL FIELD

This disclosure relates to the technical field of semiconductor, and particularly to a method for micro-LED epitaxial wafer manufacturing and a micro-LED epitaxial wafer.

### BACKGROUND

At present, micro LEDs are manufactured as follows. An epitaxial wafer is obtained with a metal-organic chemical vapour deposition (MOCVD) machine. After the desired size of each micro-LED chip of the epitaxial wafer is determined with photoresist, positive and negative electrodes are provided for each micro-LED chip. The epitaxial wafer is cut to obtain the micro-LED chips. However, in the existing manufacturing method, atomic bond breaking (i.e., dangling bond) may occur around an epitaxial structure of the cut micro-LED chip. Atomic bond breaking will lead to capture of electrons and electron holes, resulting in a decrease in an efficiency of recombination between electrons and electron holes. Moreover, the smaller the size of the cut micro-LED chip, the lower the efficiency of the recombination.

In sum, the existing technology needs to be improved and developed.

### SUMMARY

In view of the above deficiencies, a method for micro-LED epitaxial wafer manufacturing and a micro-LED epitaxial wafer are provided, which can avoid atomic bond breaking caused by directly cutting grown epitaxial wafer, thereby improving an efficiency of recombination between electrons and electron holes.

In a first aspect of the disclosure, a method for micro-LED epitaxial wafer manufacturing is provided. For each growth region of a micro-LED chip on a growth substrate, photoresist is applied to the growth region. For each growth region, an epitaxial isolation wall is grown at a boundary of the growth region. For each growth region, the photoresist on the growth substrate is removed with the epitaxial isolation wall remained. For each growth region, a first semiconductor layer, a light-emitting layer, and a second semiconductor layer are grown in the growth region to obtain a micro-LED epitaxial structure. The growth substrate is cut along the epitaxial isolation wall, to obtain at least two micro-LED epitaxial structures.

In one implementation, the first semiconductor layer, the light-emitting layer, and the second semiconductor layer are grown in the growth region to obtain the micro-LED epitaxial structure as follows. The growth substrate is placed into a metal-organic chemical vapour deposition (MOCVD) machine to grow an undoping semiconductor layer and the first semiconductor layer on the growth substrate. A portion of the first semiconductor layer is thinned, where the portion is within a preset range of the epitaxial isolation wall. The first semiconductor layer, the light-emitting layer, the second semiconductor layer, a first ohmic metal layer, and a second ohmic metal layer are successively grown on the growth substrate.

In one implementation, the first semiconductor layer, the light-emitting layer, and the second semiconductor layer are grown in the growth region to obtain the micro-LED epitaxial structure as follows. The growth substrate is placed into an MOCVD machine to grow the first semiconductor layer on the growth substrate. A portion of the first semiconductor layer is thinned, where the portion is within a preset range of the epitaxial isolation wall. The first semiconductor layer, the light-emitting layer, the second semiconductor layer, a first ohmic metal layer, and a second ohmic metal layer are successively grown on the growth substrate.

In one implementation, after growing the first semiconductor layer, the light-emitting layer, and the second semiconductor layer in the growth region to obtain the micro-LED epitaxial structure, and prior to cutting the growth substrate along the epitaxial isolation wall to obtain the at least two micro-LED epitaxial structures, the growth substrate is thinned and a back surface of the growth substrate is polished.

In one implementation, the epitaxial isolation wall has a height greater than or equal to a total height of the micro-LED epitaxial structure.

In one implementation, the growth substrate is a sapphire substrate.

In a second aspect of the disclosure, a micro-LED epitaxial wafer is provided. The micro-LED epitaxial wafer includes a growth substrate, at least one epitaxial isolation wall, and at least one micro-LED chip structure. The epitaxial isolation wall is disposed on the growth substrate to form at least two growth regions for micro-LED chips. The micro-LED chip structure includes a micro-LED epitaxial structure. The micro-LED epitaxial structure includes a first semiconductor layer, a light-emitting layer, and a second semiconductor layer stacked in sequence.

In one implementation, the micro-LED chip structure further includes at least one metal layer.

In one implementation, the micro-LED chip structure further includes an undoping semiconductor layer grown between the growth substrate and the first semiconductor layer.

In one implementation, the epitaxial isolation wall has a height greater than or equal to a total height of the micro-LED epitaxial structure.

In one implementation, the growth substrate is a sapphire substrate.

Advantageous effects: according to the method of the implementations of the disclosure, for each growth region of a micro-LED chip on a growth substrate, photoresist is applied to the growth region. For each growth region, an epitaxial isolation wall is grown at a boundary of the growth region. For each growth region, the photoresist on the growth substrate is removed with the epitaxial isolation wall remained. For each growth region, a first semiconductor layer, a light-emitting layer, and a second semiconductor layer are grown in the growth region to obtain a micro-LED epitaxial structure. The growth substrate is cut along the epitaxial isolation wall, to obtain at least two micro-LED epitaxial structures. In the disclosure, the epitaxial isolation wall for each growth region of the micro-LED chip can be grown, and the growth substrate can be cut along the epitaxial isolation wall, which can avoid atomic bond breaking caused by directly cutting grown epitaxial wafer, thereby improving an efficiency of recombination between electrons and electron holes.

### BRIEF DESCRIPTION OF THE DRAWINGS

In order to describe technical solutions of implementations or the related art more clearly, the following will give a brief description of accompanying drawings used for describing the implementations or the related art. Apparently, accompanying drawings described below are merely some implementations. Those of ordinary skill in the art can also obtain other accompanying drawings based on the accompanying drawings described below without creative efforts.

FIG. 1A is a schematic structural diagram illustrating a wafer after photolithography according to implementations.

FIG. 1B is a schematic structural diagram illustrating a wafer with epitaxial isolation walls according to implementations.

FIG. 1C is a schematic structural diagram illustrating a wafer removing photoresist with the epitaxial isolation walls remained according to implementations.

FIG. 1D is a schematic structural diagram illustrating a wafer with micro-LED epitaxial structures according to implementations.

FIG. 2 is a schematic flowchart illustrating a method for micro-LED epitaxial wafer manufacturing according to implementations.

FIG. 3 is a schematic diagram illustrating growth of a first semiconductor layer according to implementations.

FIG. 4 is a schematic structural diagram illustrating a structure corresponding to a surface mount technology (SMT) LED chip according to implementations.

FIG. 5 is a schematic structural diagram illustrating a structure corresponding to an LED flip chip according to implementations.

FIG. 6 is a schematic structural diagram illustrating a structure corresponding to a vertical LED chip according to implementations.

### DETAILED DESCRIPTION

In order for those skilled in the art to better understand technical solutions of implementations of the disclosure, the technical solutions of the implementations will be described clearly and completely with reference to accompanying drawings in the implementations. Apparently, implementations described hereinafter are merely some implementations, rather than all implementations of the disclosure. All other implementations obtained by those of ordinary skill in the art based on the implementations without creative efforts shall fall within the protection scope of the disclosure.

The existing method for micro-LED epitaxial wafer manufacturing is as follows. An epitaxial wafer is obtained by growing a micro-LED chip structure(s) on a wafer. After the desired size of each micro-LED chip is determined with photoresist, the epitaxial wafer is cut to obtain micro-LED chips. However, the inventor of the disclosure realizes through researches that according to the existing method for micro-LED epitaxial wafer manufacturing, atomic bond breaking may occur around an epitaxial structure of the cut micro-LED chip, which leads to decrease of an efficiency of recombination between electrons and electron holes. Moreover, the smaller the size of the cut micro-LED chip, the lower the efficiency of the recombination.

In view of the above deficiencies in the related art, in the disclosure, the epitaxial isolation wall between growth regions of micro-LED chips is grown and the growth substrate is cut along the epitaxial isolation wall. As such, atomic bond breaking caused by directly cutting grown epitaxial wafer can be avoided, thereby improving the efficiency of the recombination between electrons and electron holes.

Hereinafter, illustrative implementations of the disclosure will be described in detail with reference to the accompanying drawings.

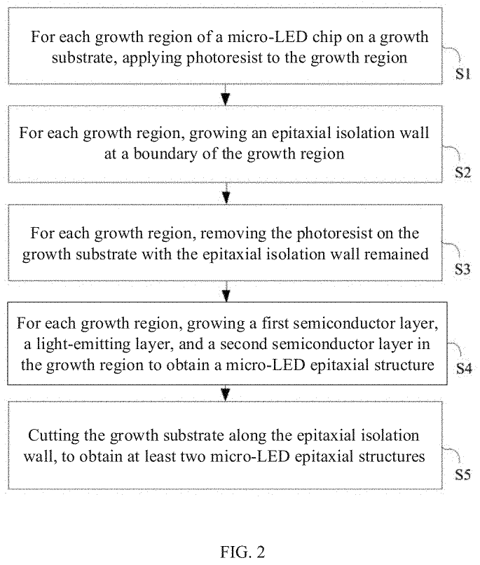

In implementations of the disclosure, a method for micro-LED epitaxial wafer manufacturing is provided. As illustrated in FIG. 2, the method includes the following.

At block S1, for each growth region of a micro-LED chip on a growth substrate, photoresist is applied to the growth region.

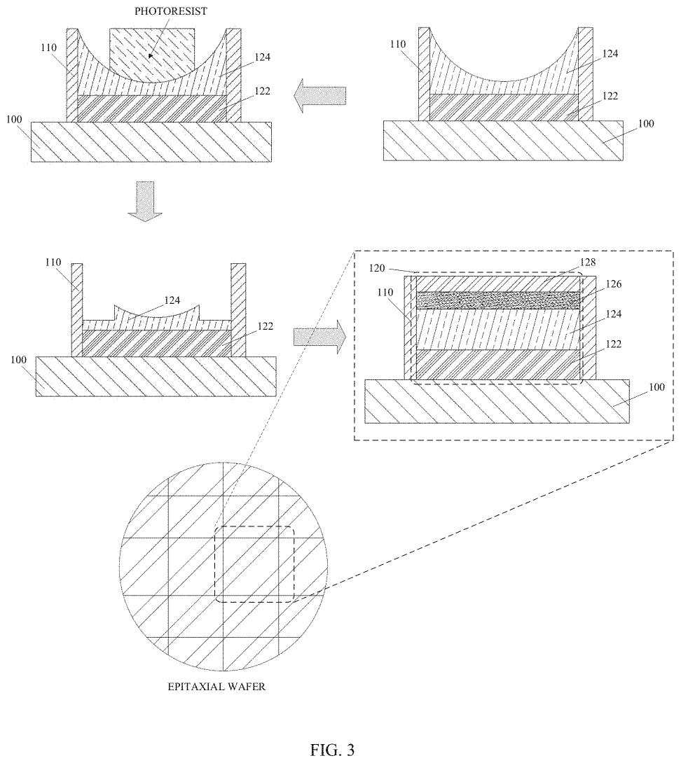

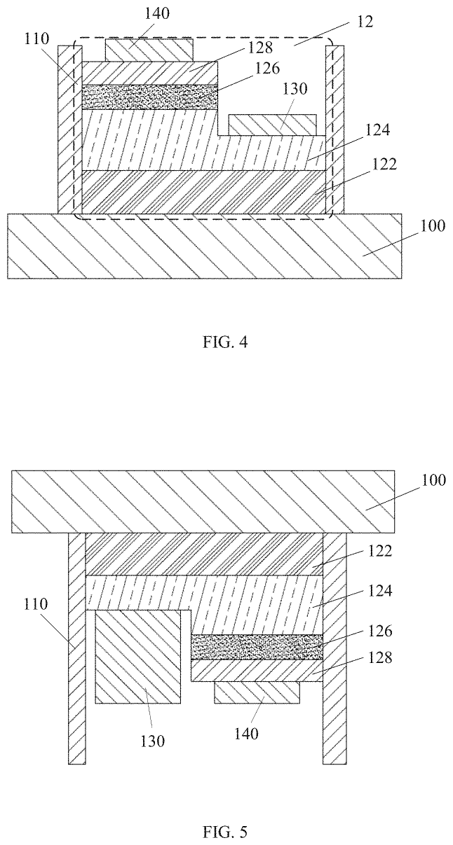

In implementations of the disclosure, a micro-LED chip structure is grown in a growth region of the micro-LED chip. The micro-LED chip structure includes a micro-LED epitaxial structure, a positive electrode, and a negative electrode. The micro-LED epitaxial structure includes a first semiconductor layer, a light-emitting layer, and a second semiconductor layer. After growth of the micro-LED chip structure is completed, the combination of the growth substrate and micro-LED chip structures is cut to obtain multiple micro-LED chips. For example, as illustrated in FIG. 3 to FIG. 4, a micro-LED chip structure 12 includes a micro-LED epitaxial structure 120, a positive electrode 140, and a negative electrode 130. The micro-LED epitaxial structure 120 includes an undoping semiconductor layer 122, a first semiconductor layer 124, a light-emitting layer 126, and a second semiconductor layer 128.

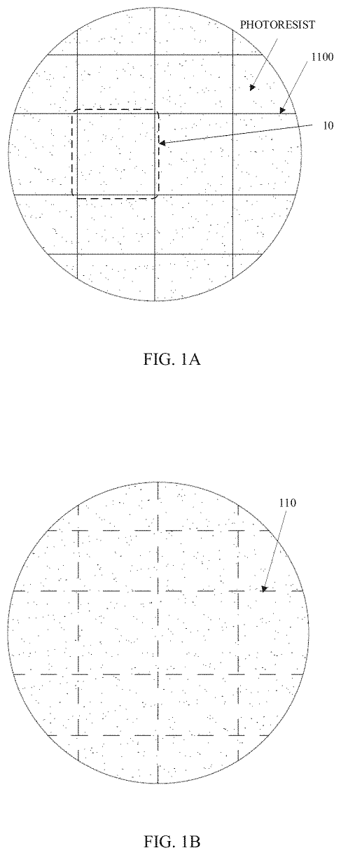

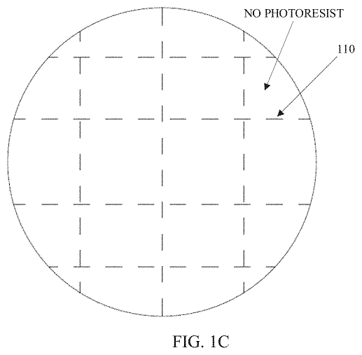

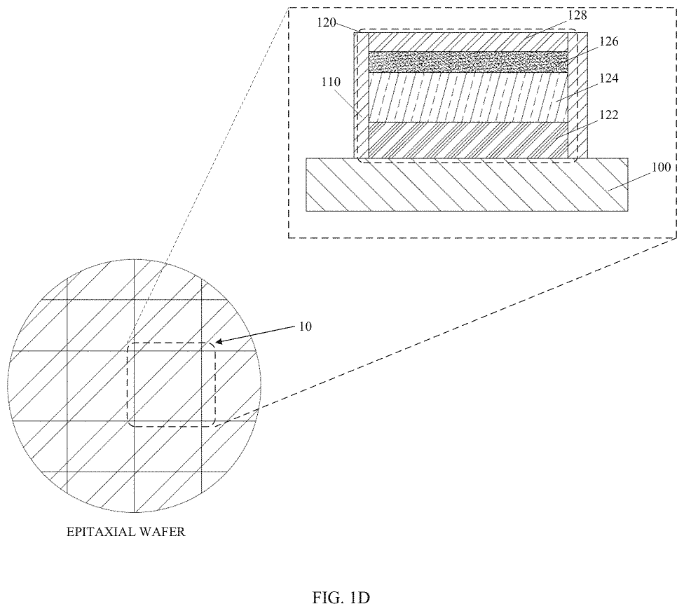

The photoresist is a light-sensitive material commonly used in an industrial process. In implementations of the disclosure, as illustrated in FIG. 1A to FIG. 1D, the photoresist is coated on the growth substrate 100. Then multiple growth regions 10 are formed by drawing multiple growth boundaries on the growth substrate 100 through photolithography, that is, each growth region 10 is covered with the photoresist after photolithography. The covered area of photoresist in the growth region 10 is equal to the size of the micro-LED chip. The growth region 10 of the micro-LED chip is surrounded by a photoetching groove 1100 (i.e., a region where no photoresist is coated), and the epitaxial isolation wall 110 is disposed in the groove 1100. In this way, the epitaxial isolation wall 110 can grow along the boundary of the growth region 10, thereby isolating each growth region 10.

In implementations of the disclosure, the micro-LED chip to-be-manufactured may have any suitable shape, such as square, circular, rectangular, etc. The shape of the growth region corresponds to that of the micro-LED chip to-be-manufactured, and accordingly, the growth region can be of any shape.

In implementations of the disclosure, the growth substrate may be a sapphire substrate.

At block S2, for each growth region, an epitaxial isolation wall is grown at a boundary of the growth region.

In implementations of the disclosure, as illustrated in FIG. 1A to FIG. 1D, the photoresist is coated on the growth substrate 100. Then growth regions 10 of micro-LED chips are drawn on the growth substrate 100 through photolithography, that is, each growth region 10 of the micro-LED chip on the growth substrate 100 is covered with the photoresist. The growth region 10 of the micro-LED chip is surrounded by a photoetching groove 1100 (i.e., a region where no photoresist is coated), and the epitaxial isolation wall 110 is disposed in the groove 1100.

In implementations of the disclosure, the epitaxial isolation wall is configured to isolate the growth regions. The epitaxial isolation wall may be made of SiO₂, SiOₓ, or SiNₓ. The epitaxial isolation wall may also be made of a high temperature resistance oxide or nitride. The upper temperature limit of the material of the epitaxial isolation wall is higher than 1200° C. In addition, the height of the epitaxial isolation wall is greater than or equal to the total height of an epitaxial structure. In this way, micro-LED chip structures grown on the growth substrate can be completely isolated from each other by the epitaxial isolation wall(s), thus avoiding atomic bond breaking due to cutting.

At block S3, for each growth region, the photoresist on the growth substrate is removed with the epitaxial isolation wall retained.

The photoresist in each growth region is removed, so that the micro-LED chip structure(s) can be grown on the growth substrate provided with the epitaxial isolation wall(s).

At block S4, for each growth region, a first semiconductor layer, a light-emitting layer, and a second semiconductor layer are grown in the growth region to obtain a micro-LED epitaxial structure.

In one implementation, the operations at block S4 include the following. As illustrated in FIG. 3 to FIG. 6, at S411, the growth substrate 100 is placed into a metal-organic chemical vapour deposition (MOCVD) machine to grow an undoping semiconductor layer 122 and the first semiconductor layer 124 on the growth substrate 100. At S412, a portion of the first semiconductor layer 124 is thinned, where the portion is within a preset range of the epitaxial isolation wall 110. At S413, the first semiconductor layer 124, the light-emitting layer 126, the second semiconductor layer 128, a first ohmic metal layer 130, and a second ohmic metal layer 140 are successively grown on the growth substrate 100.

Since the first semiconductor layer is grown with the MOCVD machine, a portion of the first semiconductor layer close to the epitaxial isolation wall is relatively thick while a middle portion of the first semiconductor layer is relatively thin. To this end, the thickness of the portion of the first semiconductor layer close to the epitaxial isolation wall is decreased through a yellow light lithography process and a dry etching method (e.g., inductively coupled plasma (ICP) etching).

At S412, the first semiconductor layer is grown initially and the thickness of the first semiconductor layer is preprocessed. At S413, the first semiconductor layer is continuously grown with the MOCVD machine on the preprocessed growth substrate (i.e., preprocessed at S412). After growth of the first semiconductor layer is completed, the light-emitting layer, the second semiconductor layer, the first ohmic metal layer, and the second ohmic metal layer are sequentially grown with the MOCVD machine.

In implementations of the disclosure, the undoping semiconductor layer may be an undoping gallium nitride layer (undoping GaN), the first semiconductor layer may be an N-type doping gallium nitride layer (n-GaN), the second semiconductor layer may be a P-type doping gallium nitride layer (p-GaN), the first ohmic metal layer may be an electrode (N-pad) connected to the N-type doping gallium nitride layer, the second ohmic metal layer may be an electrode (P-pad) connected to the P-type doping gallium nitride layer.

Based on the foregoing operations, as illustrated in FIG. 4 to FIG. 5, a surface mount technology (SMT) LED chip, a LED flip chip, or a LED thin film flip chip (similar to the structure of the LED flip chip) can be obtained.

In another implementation, the operations at block S4 include the following. At S421, the growth substrate is placed into an MOCVD machine to grow the first semiconductor layer on the growth substrate. At S422, a portion of the first semiconductor layer is thinned, where the portion is within a preset range of the epitaxial isolation wall. At S423, the first semiconductor layer, the light-emitting layer, the second semiconductor layer, a first ohmic metal layer, and a second ohmic metal layer are successively grown on the growth substrate.

Since the first semiconductor layer is grown with the MOCVD machine, a portion of the first semiconductor layer close to the epitaxial isolation wall is relatively thick while a middle portion of the first semiconductor layer is relatively thin. To this end, the thickness of the portion of the first semiconductor layer close to the epitaxial isolation wall is decreased through a yellow light lithography process and a dry etching method.

At S422, the first semiconductor layer is grown initially and the thickness of the first semiconductor layer is preprocessed. At S423, the first semiconductor layer is continuously grown with the MOCVD machine on the preprocessed growth substrate (i.e., preprocessed at S422). After growth of the first semiconductor layer is completed, the light-emitting layer, the second semiconductor layer, the first ohmic metal layer, and the second ohmic metal layer are sequentially grown with the MOCVD machine.

In implementations of the disclosure, the first semiconductor layer may be made of p-GaN, the second semiconductor layer may be made of n-GaN, the first ohmic metal layer may be made of N-pad, and the second ohmic metal layer may be made of P-pad.

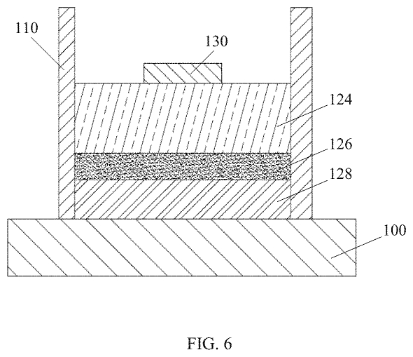

Based on the foregoing operations, as illustrated in FIG. 6, a vertical LED chip can be obtained.

At block S5, the growth substrate is cut along the epitaxial isolation wall, to obtain at least two micro-LED epitaxial structures.

In implementations of the disclosure, prior to cutting the growth substrate along the epitaxial isolation wall, the growth substrate is thinned and a back surface of the growth substrate is polished.

In the disclosure, the epitaxial isolation wall can be provided between micro-LED chips to-be-grown on the growth substrate to isolate the micro-LED chips from each other, which can avoid breaking of atomic bonds around an epitaxial structure of the cut micro-LED chip in a traditional epitaxial wafer manufacturing process. In addition, warpage of the growth substrate can be reduced, which improves wavelength uniformity of the epitaxial structure and the light-emitting layer.

In implementation of the disclosure, a micro-LED epitaxial wafer is provided. The micro-LED epitaxial wafer is grown with the foregoing method. The micro-LED epitaxial wafer includes a growth substrate, at least one epitaxial isolation wall, and at least one micro-LED chip structure. The epitaxial isolation wall is disposed on the growth substrate to form at least two growth regions for micro-LED chips. The micro-LED chip structure includes a micro-LED epitaxial structure. The micro-LED epitaxial structure includes a first semiconductor layer, a light-emitting layer, and a second semiconductor layer stacked in sequence.

In one implementation, the micro-LED chip structure further includes at least one metal layer.

In one implementation, the micro-LED chip structure further includes an undoping semiconductor layer grown between the growth substrate and the first semiconductor layer.

In the disclosure, the epitaxial isolation wall can be provided between micro-LED chips to-be-grown on the growth substrate to isolate the micro-LED chips from each other, which can avoid breaking of atomic bonds around an epitaxial structure of the cut micro-LED chip in a traditional epitaxial wafer manufacturing process. In addition, warpage of the growth substrate can be reduced, which improves wavelength uniformity of the epitaxial structure and the light-emitting layer.

Technical features of the foregoing implementations may be combined in any manner. For the sake of simplicity, not all possible combinations of the technical features of the foregoing implementations are described. The combinations of these technical features shall all be encompassed within the protection of the disclosure without conflict.

The foregoing description merely depicts some illustrative implementations of the disclosure, which however are not intended to limit the disclosure. Any modifications, equivalent substitutions, or improvements made by those skilled in the art without departing from the spirits and principles of the disclosure shall all be encompassed within the protection scope of the disclosure. The protection scope of the disclosure should be defined by the appended claims and equivalents of the appended claims.

What is claimed is:

1. A method for micro-LED epitaxial wafer manufacturing, comprising:
for each growth region of a micro-LED chip on a growth substrate,
applying photoresist to the growth region;
growing an epitaxial isolation wall at a boundary of the growth region;
removing the photoresist on the growth substrate with the epitaxial isolation wall remained; and
growing a first semiconductor layer, a light-emitting layer, and a second semiconductor layer in the growth region to obtain a micro-LED epitaxial structure; and
cutting the growth substrate along the epitaxial isolation wall, to obtain at least two micro-LED epitaxial structures.

2. The method for micro-LED epitaxial wafer manufacturing of claim 1, wherein growing the first semiconductor layer, the light-emitting layer, and the second semiconductor layer in the growth region to obtain the micro-LED epitaxial structure comprises:
placing the growth substrate into a metal-organic chemical vapour deposition (MOCVD) machine to grow an undoping semiconductor layer and the first semiconductor layer on the growth substrate;
thinning a portion of the first semiconductor layer, wherein the portion is within a preset range of the epitaxial isolation wall; and
growing the first semiconductor layer, the light-emitting layer, the second semiconductor layer, a first ohmic metal layer, and a second ohmic metal layer successively on the growth substrate.

3. The method for micro-LED epitaxial wafer manufacturing of claim 1, wherein growing the first semiconductor layer, the light-emitting layer, and the second semiconductor layer in the growth region to obtain the micro-LED epitaxial structure comprises:
placing the growth substrate into an MOCVD machine to grow the first semiconductor layer on the growth substrate;
thinning a portion of the first semiconductor layer, wherein the portion is within a preset range of the epitaxial isolation wall; and
growing the first semiconductor layer, the light-emitting layer, the second semiconductor layer, a first ohmic metal layer, and a second ohmic metal layer successively on the growth substrate.

4. The method for micro-LED epitaxial wafer manufacturing of claim 1, further comprising:
after growing the first semiconductor layer, the light-emitting layer, and the second semiconductor layer in the growth region to obtain the micro-LED epitaxial structure, and prior to cutting the growth substrate along the epitaxial isolation wall to obtain the at least two micro-LED epitaxial structures,
thinning the growth substrate and polishing a back surface of the growth substrate.

5. The method for micro-LED epitaxial wafer manufacturing of claim 1, wherein the epitaxial isolation wall has a height greater than or equal to a total height of the micro-LED epitaxial structure.

6. The method for micro-LED epitaxial wafer manufacturing of claim 1, wherein the growth substrate is a sapphire substrate.

7. A micro-LED epitaxial wafer, comprising:
a growth substrate;
at least one epitaxial isolation wall, disposed on the growth substrate to form at least two growth regions for micro-LED chips; and
at least one micro-LED chip structure, the micro-LED chip structure comprising a micro-LED epitaxial structure, the micro-LED epitaxial structure comprising a first semiconductor layer, a light-emitting layer, and a second semiconductor layer stacked in sequence.

8. The micro-LED epitaxial wafer of claim 7, wherein the micro-LED chip structure further comprises at least one metal layer.

9. The micro-LED epitaxial wafer of claim 7, wherein the micro-LED chip structure further comprises an undoping semiconductor layer grown between the growth substrate and the first semiconductor layer.

10. The micro-LED epitaxial wafer of claim 7, wherein the epitaxial isolation wall has a height greater than or equal to a total height of the micro-LED epitaxial structure.

11. The micro-LED epitaxial wafer of claim 7, wherein the growth substrate is a sapphire substrate.
